(19) United States
(12) Patent Application Publication
(10) Pub. No.: US 2007/0057738 A1
(43) Pub. Date: Mar. 15, 2007

(54) Oscillator device and transmission and reception device

(76) Inventors: Takahiro Baba, Omihachiman-shi (JP); Toshiro Hiratsuka, Kusatsu-shi (JP); Tomiya Sonoda, Yokohama-shi (JP)

Correspondence Address: DICKSTEIN SHAPIRO LLP, 1177 AVENUE OF THE AMERICAS (6TH AVENUE), NEW YORK, NY, 10036-2714, US

(21) Appl. No.: 10/562,569

(22) PCT Filed: Jul. 1, 2004
(86) PCT No.: PCT/JP04/09319

§ 371 Date: Jun. 19, 2006

(30) Foreign Application Priority Data
Jul. 2, 2003 (JP) 2003-190488

(51) Int. Cl. H03L 7/00

(52) U.S. Cl. 331/34

(57) ABSTRACT

An oscillator device and a transmission and reception device that are usable for implementing high output and wide-band modulation and that can reduce the manufacturing cost. An oscillation circuit and a frequency control circuit including microstrip lines are formed on an oscillation circuit substrate. A TM010 mode resonator including resonator electrodes are formed on a dielectric substrate along with excitation electrodes to form a dielectric resonator chip. One of the resonator electrodes is fixed to a land of the oscillation circuit substrate with bumps, and also, the excitation electrodes are fixed to the microstrip with bumps. With this configuration, the TM010 mode resonator can be excited by using the excitation electrodes, and also, the dielectric resonator chip can be miniaturized and the manufacturing cost can be decreased accordingly.

### TECHNICAL FIELD

The present invention relates to an oscillator device for oscillating high-frequency electromagnetic waves, such as microwaves and millimeter waves, and also to a transmission and reception device, such as a communication device or a radar device, using the oscillator device.

### BACKGROUND ART

In general, a high-frequency oscillator device including an oscillation circuit for oscillating a signal having a predetermined oscillating frequency and a dielectric resonator, such as a TM010 mode resonator, for setting the oscillating frequency are disposed on a dielectric substrate is known for use in, for example, a communication device, (for example, see Patent Document 1).

Patent Document 1: Japanese Unexamined Patent Application Publication No. 11-330818

In the oscillator device according to the first related art, the oscillation circuit and the dielectric resonator are disposed side by side on the same dielectric substrate, and are connected to each other by using ribbons or wires. Accordingly, in the first related art, electromagnetic waves of the oscillation circuit and electromagnetic waves of the dielectric resonator can be directly coupled with each other, thereby enhancing a coupling force therebetween.

As the second related art, the following oscillator device is known (for example, see Non-Patent Document 1). An oscillation circuit is formed on a substrate and a TE010 mode resonator is formed on another substrate, and the TE010 mode resonator is fixed on the substrate of the oscillation circuit. In the related art, the oscillator exhibiting excellent noise characteristics can be formed since the TE010 mode resonator has high Q (Quality factor) characteristics.

Non-Patent Document 1: K. SAKAMOTO et al, “A Millimeter Wave DR-VCO on Planar Type Dielectric Resonator with Small Size and Low Phase Noise”, IEICE Trans. Electron., IEICE, Japan, January 1999, Vol. E82-C, No. 1, pp. 119-125

In the oscillator device according to the first related art, in addition to the oscillation circuit, a frequency control circuit for controlling the oscillating frequency and a terminating resistor are disposed on the dielectric substrate of the dielectric resonator. The dielectric substrate used for the dielectric resonator is expensive since it has a high dielectric constant. In this case, the area of the dielectric substrate is large, which increases the manufacturing cost of the overall oscillator device.

Additionally, the dielectric resonator and the oscillation circuit are disposed side by side and are connected to each other by using ribbons or wires. This increases variations in the characteristics of the oscillator devices in the high frequency band (in particular, in millimeter-wave band).

In the second related art, the use of the TE010 mode resonator enhances magnetic-field confinement characteristics in the direction parallel with the electrode surface of the resonator. This makes it difficult to establish coupling with the external lines of the oscillation circuit. Accordingly, this type of oscillator is not suitable as an oscillator device used for implementing high output wide-band modulation, which requires strong coupling with the oscillation circuit.

Additionally, it is necessary that cavities be provided on the top and bottom (front and back) of the electrode surface of the TE010 mode resonator, thereby increasing the complexity of the overall oscillator device and increasing the manufacturing cost accordingly.

In the TE010 mode resonator, magnetic fields are extended in the direction perpendicular to the electrode surface. It is thus necessary that cover and bottom conductors forming the cavities be disposed separately from the electrode surface of the resonator by a certain distance. This makes it difficult to decrease the height of the oscillator device.

### DISCLOSURE OF INVENTION

The present invention has been made in terms of the above-described problems unique to the related art. An object of the present invention is to provide an oscillator device and a transmission and reception device that are usable for implementing high output and wide-band modulation and that can reduce the manufacturing cost.

To solve the above-described problems, the present invention provides an oscillator device including an oscillation circuit substrate, an oscillation circuit disposed on the oscillation circuit substrate to oscillate a signal having a predetermined oscillating frequency, and a dielectric resonator for setting the oscillating frequency. The dielectric resonator includes a dielectric substrate mounted on a front surface of the oscillation circuit substrate, a TM010 mode resonator having electrodes disposed on both surfaces of the dielectric substrate, at least one of the electrodes being circular, and an excitation electrode disposed on the dielectric substrate, the excitation electrode being connected to the oscillation circuit and being coupled with the TM010 mode resonator.

With this configuration, the TM010 mode resonator can be excited through the excitation electrode connected to the oscillation circuit, and the oscillating frequency of the oscillation circuit can be set by using the TM010 mode resonator. Both the TM010 mode resonator and the excitation electrode are disposed on the dielectric substrate.

Accordingly, variations in the coupling amount by which the resonator and the excitation electrode are coupled can be reduced compared to when, for example, the excitation electrode is disposed on the oscillation circuit substrate.

As a result, the characteristics of the individual oscillator devices can be maintained substantially at the constant level. Additionally, since the dielectric resonator is formed by the TM010 mode resonator and the excitation electrode, the provision of a frequency control circuit and a terminating resistor on the dielectric substrate can be omitted, thereby miniaturizing the dielectric substrate. Thus, by a reduction in variations in the characteristics, the mass productivity of the oscillator devices can be improved, and by using the small dielectric substrate, the manufacturing cost can be decreased. By the use of the TM010 mode resonator, high output and wide-band modulation can be achieved compared to when a TE010 mode resonator is used.

In the present invention, the oscillation circuit may include a transmission line provided with a ground electrode on a back surface of the oscillation circuit substrate, and between the two electrodes of the TM010 mode resonator, the electrode disposed on a back surface of the dielectric substrate may be connected to a land disposed on the front surface of the oscillation circuit substrate, and the land may be connected to the ground electrode of the transmission line via a through-hole passing through the oscillation circuit substrate.

With this configuration, between the two electrodes of the TM010 mode resonator, the electrode disposed on the back surface of the dielectric substrate can be connected to the ground electrode of the transmission line via the land and the through-hole. This eliminates the need to provide a cavity for the TM010 mode resonator at the side of the oscillation circuit substrate (back surface of the dielectric substrate). Electric fields are excited between the electrode disposed on the top surface (front surface) of the TM010 mode resonator and a cavity in the vertical direction (thickness direction of the dielectric substrate), and thus, the frequency sensitivity is low in response to the height of the cavity. Accordingly, also on the front surface of the dielectric substrate, the sensitivity of the resonant frequency is low in response to the presence or absence of a cover. Thus, the formation of a cavity using a conductive cover is not necessary. As a result, the height of the overall resonator can be decreased, and the structure of the resonator can be simplified, thereby enhancing the mass productivity and decreasing the manufacturing cost.

In the present invention, between the two electrodes of the TM010 mode resonator, the electrode disposed on the back surface of the dielectric substrate may be connected to the land by using bumps.

With this arrangement, a connection with high positional precision can be achieved compared to when a ribbon, a wire, or a conductive paste is used for connecting the electrode on the back surface of the TM010 mode resonator and the land. Accordingly, the characteristics, such as the resonant frequency, can be maintained substantially at the constant level. As a result, variations in the characteristics of the oscillator device caused by the mounting operation for the resonator chip can be suppressed or reduced, thereby improving the mass productivity of the resonator devices.

In the present invention, the oscillation circuit may include a transmission line provided with a ground electrode on the front surface of the oscillation circuit substrate, and between the two electrodes of the TM010 mode resonator, the electrode disposed on the back surface of the dielectric substrate may be connected to the ground electrode of the transmission line disposed on the front surface of the oscillation circuit substrate.

With this configuration, between the two electrodes of the TM010 mode resonator, the electrode disposed on the back surface of the dielectric substrate can be connected to the ground electrode of the transmission line. This eliminates the need to provide a cavity for the TM010 mode resonator at the side of the oscillation circuit substrate (back surface of the dielectric substrate). Also on the front surface of the dielectric substrate, the sensitivity of the resonant frequency is low in response to the presence or absence of a cover. Thus, the formation of a cavity using a conductive cover is not necessary. As a result, the height of the overall resonator can be decreased, and the structure of the resonator can be simplified, thereby enhancing the mass productivity and decreasing the manufacturing cost.

In the present invention, a frequency control circuit for controlling the oscillating frequency may be disposed on the oscillation circuit substrate, and another excitation electrode to be coupled with the TM010 mode resonator may be disposed on the dielectric substrate, and that excitation electrode may be connected to the frequency control circuit.

With this arrangement, as in the present invention, when a counteractive resonance circuit is formed by using a TM010 mode resonator, a decrease in the unloaded Q (Qo) can be suppressed compared to when a TE010 mode resonator is used, as in the related art. Accordingly, loss caused by the resonator becomes smaller, and a high oscillation output can be expected. Additionally, strong coupling between the resonator and the frequency control circuit can be established without seriously decreasing the unloaded Q of the resonator. It is thus possible to form a voltage controlled oscillator that can perform wide-band modulation by using the frequency control circuit.

By using the oscillator device of the present invention, a transmission and reception device, such as a radar device or a communication device, may be formed. Thus, the transmission and reception device can be used in a wide band, and the manufacturing cost can be reduced.

### BRIEF DESCRIPTION OF THE DRAWINGS

FIG. 1 is a plan view illustrating an oscillator device according to a first embodiment of the present invention.

FIG. 2 is an electric circuit diagram illustrating the oscillator device shown in FIG. 1.

FIG. 3 is a perspective view illustrating a dielectric resonator chip and other components enlarged from those shown in FIG. 1.

FIG. 4 is an exploded perspective view illustrating a dielectric resonator chip and other components enlarged from those shown in FIG. 1.

FIG. 5 is an exploded plan view illustrating a dielectric resonator chip and other components enlarged from those shown in FIG. 1.

FIG. 6 is an enlarged plan view illustrating the dielectric resonator chip only shown in FIG. 1.

FIG. 7 is an enlarged bottom view illustrating the dielectric resonator chip only shown in FIG. 1.

FIG. 8 is an exploded perspective view illustrating a computation model of, for example, a dielectric resonator chip.

FIG. 9 is a sectional view illustrating the computation model of, for example, a dielectric resonator chip, taken along line IX-IX in FIG. 8.

FIG. 10 is a characteristic diagram illustrating the relationship between the gap formed in the dielectric resonator chip shown in FIG. 9 and the resonant frequency and the electric energy concentration.

FIG. 11 is a characteristic diagram illustrating the relationship between the frequency and the reflection loss caused by the dielectric resonator chip shown in FIG. 1.

FIG. 12 is a characteristic diagram enlarged from the diagram having a frequency range from 37.5 GHz to 38.5 GHz in FIG. 11.

FIG. 13 is an enlarged plan view illustrating a dielectric resonator chip according to a first modified example.

FIG. 14 is an enlarged bottom view illustrating the dielectric resonator chip shown in FIG. 13.

FIG. 15 is an enlarged plan view illustrating a dielectric resonator chip according to a second modified example.

FIG. 16 is an enlarged bottom view illustrating the dielectric resonator chip shown in FIG. 15.

FIG. 17 is a block diagram illustrating a communication device according to a second embodiment.

### REFERENCE NUMERALS

1 oscillator substrate circuit
2 oscillation circuit
3 FET
4 ground electrode
5, 16 microstrip lines (transmission lines)
15 frequency control circuit
17 variable capacitance diode
19 land
20 through-hole
21 dielectric resonator chip (dielectric resonator)
22 dielectric substrate
23, 31 TM010 mode resonators
23A, 23B, 23A′, 23B′, 31A, 31B resonator electrodes (electrodes)
24, 25, 24′, 25′, 33 excitation electrodes
26 bumps
41 communication device (transmission and reception device)
56 oscillator device

### BEST MODE FOR CARRYING OUT THE INVENTION

An oscillator device and a communication device according to embodiments of the present invention are described in detail below with reference to the accompanying drawings.

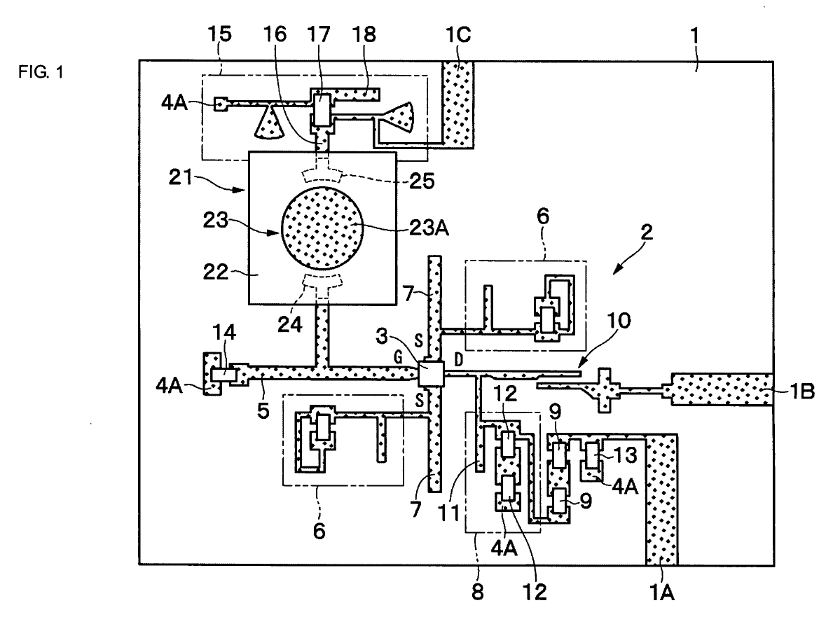

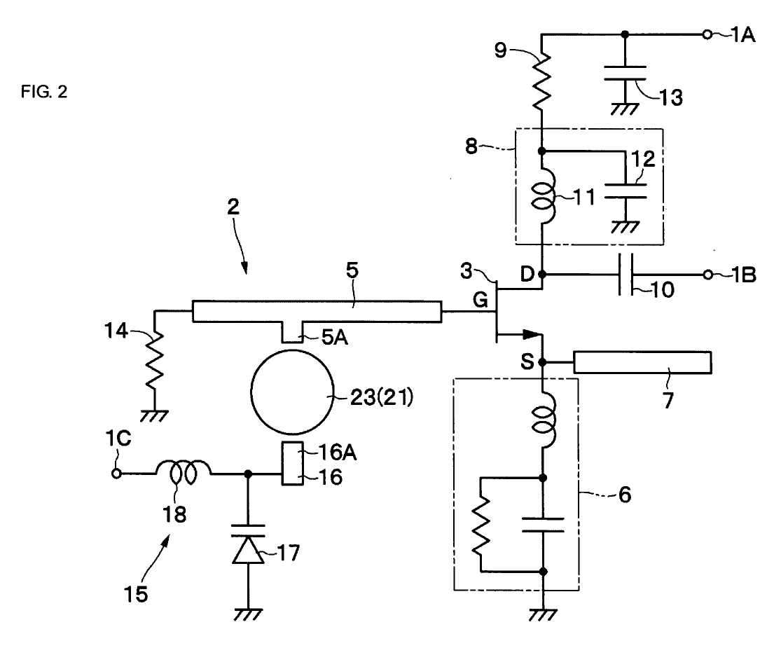

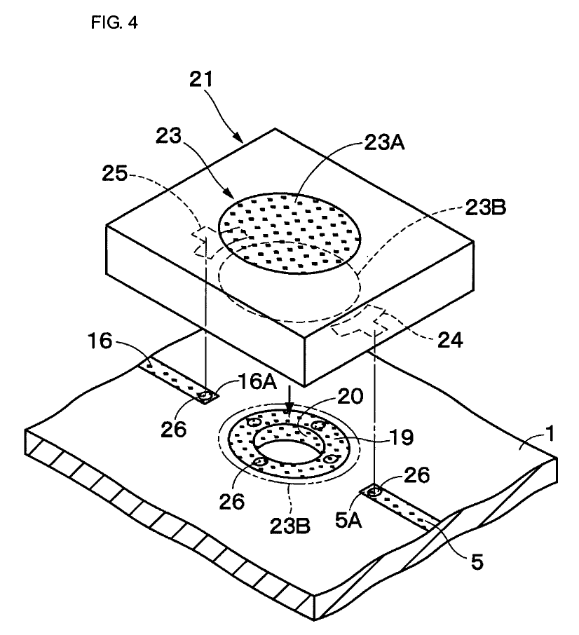

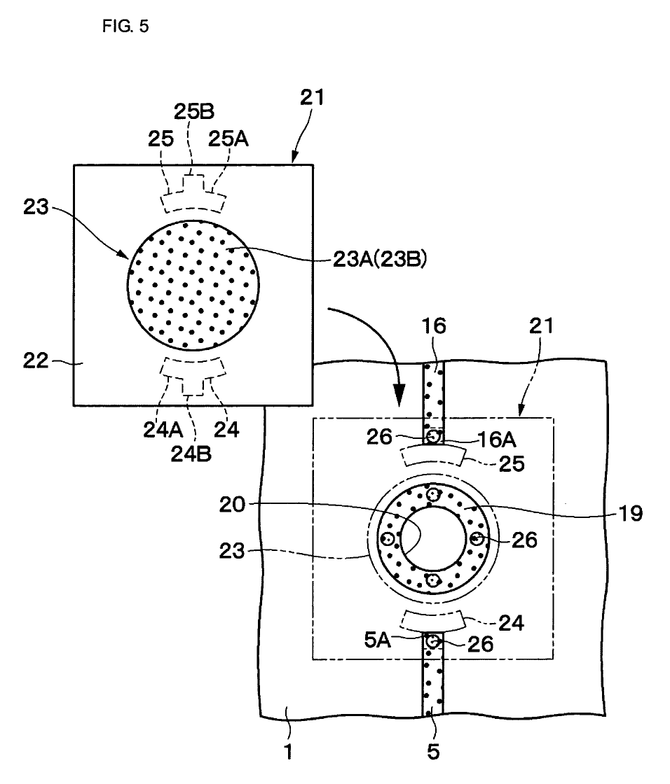

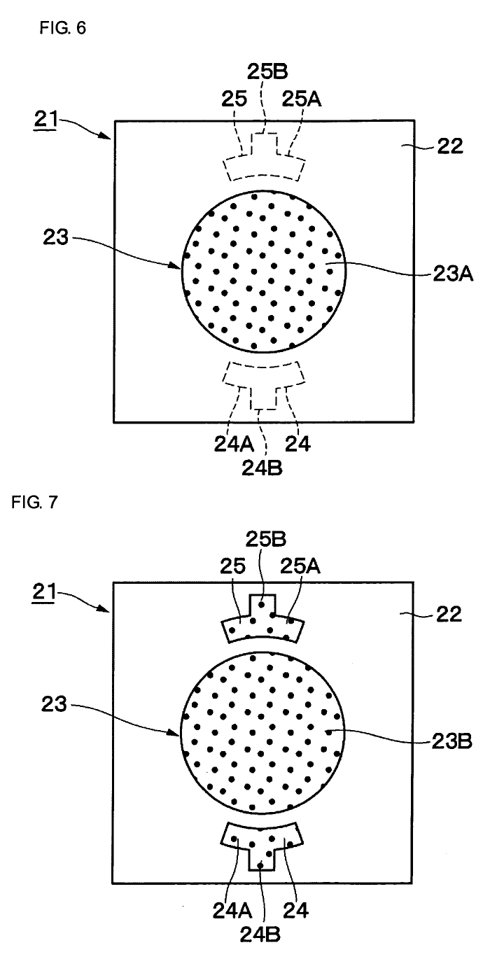

FIGS. 1 through 7 illustrate an oscillator device according to a first embodiment. In the drawings, reference numeral 1 indicates an oscillation circuit substrate formed of a dielectric material. The oscillation circuit substrate 1 having generally a quadrilateral planar shape is formed of a ceramic material, a resin material, etc., having a lower dielectric constant than, for example, a dielectric substrate 22, which is discussed below.

Reference numeral 2 indicates an oscillation circuit disposed on the front surface of the oscillation circuit substrate 1. The oscillation circuit 2 is formed of a FET 3, a microstrip line 5, bias circuits 6, etc., which are discussed below. A power supply voltage is supplied to the oscillation circuit 2 via a power terminal 1A, and the oscillation circuit 2 oscillates a signal having a predetermined oscillating frequency which is set by a dielectric resonator chip 21, which is discussed below, and outputs the signal via an output terminal 1B.

Reference numeral 3 indicates a field-effect transistor (hereinafter referred to as the “FET”3), which serves as an amplifying element, disposed on the front surface of the oscillation circuit substrate 1. A gate terminal G of the FET 3 is connected to the base terminal of the microstrip line 5, which serves as a transmission line, provided with a ground electrode 4 disposed substantially on the entire back surface of the oscillation circuit substrate 1. Source terminals S of the FET 3 are connected to the bias circuits 6 at the source side and are also connected to inductive stubs 7 formed of a microstrip line. The inductive stubs 7 function as inductors for controlling the feedback frequency.

A drain terminal D of the FET 3 is connected to the power terminal 1A via a filter circuit 8 and bias resistors 9, and is also connected to the output terminal 1B via a coupled line 10 for cutting off DC components. The filter circuit 8 includes an inductive stub 11, which serves as a choke coil, connected between the drain terminal D and the bias resistor 9, and a capacitor 12 connected at one end to a node between the inductive stub 11 and the bias resistor 9. The other end of the capacitor 12 is connected to a ground terminal 4A. A surge eliminating capacitor 13 is connected between the power terminal 1A and the ground terminal 4A.

The tip of the microstrip line 5 is connected to a ground terminal 4A through a terminating resistor 14 formed of a chip resistor, and the microstrip line 5 is branched off toward the dielectric resonator chip 21, which is discussed below, generally in a T-like shape in the middle portion of the longitudinal microstrip line 5, and the tip of the branched portion serves as a connecting portion 5A to be connected to an excitation electrode 24, which is described below. Each ground terminal 4A is connected to the ground terminal 4 by using, for example, through-holes.

Reference numeral 15 indicates a frequency control circuit disposed on the front surface of the oscillation circuit substrate 1. The frequency control circuit 15 is disposed at the side opposite to the oscillation circuit 2 across the dielectric resonator chip 21, which is described below. The frequency control circuit 15 mainly includes a microstrip line 16 connected at one end to the dielectric resonator chip 21 and a variable capacitance diode 17 (varactor diode), which serves as a modulation element, connected to the other end of the microstrip line 16.

The cathode terminal of the variable capacitance diode 17 is connected to the microstrip line 16, and the anode terminal thereof is connected to the ground terminal 4A. The cathode terminal of the variable capacitance diode 17 is connected to a control input terminal 1C via an inductive stub 18, which serves as a choke coil. The tip of the microstrip line 16 serves as a connecting portion 16A to be connected to an excitation electrode 25, which is described below.

The frequency control circuit 15 changes the capacitance of the variable capacitance diode 17 in accordance with a control voltage applied to the control input terminal 1C to control the oscillating frequency (resonant frequency).

Reference numeral 19 indicates a land located between the oscillation circuit 2 and the frequency control circuit 15 and provided on the front surface of the oscillation circuit substrate 1. The land 19 is formed of a conductive thin film, such as a metallic material. The land 19 has a circular shape smaller than a resonator electrode 23B of a TM010 mode resonator 23, which is described below, and a through-hole 20 having a metal-plated inner wall portion and passing through the oscillation circuit substrate 1 is provided at the central portion of the land 19. The land 19 is connected via the through-hole 20 to the ground electrode 4 disposed on the back surface of the oscillation circuit substrate 1.

Reference numeral 21 indicates the dielectric resonator chip, which serves as a dielectric resonator, disposed between the oscillation circuit 2 and the frequency control circuit 15. The dielectric resonator chip 21 includes the dielectric substrate 22, the TM010 mode resonator 23, and the excitation electrodes 24 and 25, which are discussed below, and sets the oscillating frequency of the oscillator device.

Reference numeral 22 indicates the dielectric substrate, which forms the main body of the dielectric resonator chip 21. The dielectric substrate 22 is formed of, for example, a ceramic material having a higher dielectric constant than the oscillation circuit substrate 1, and is formed generally in a quadrilateral planar (chip-like) shape thicker than the oscillation circuit substrate 1. The dielectric substrate 22 is overlaid on the front surface of the oscillation circuit substrate 1 such that it is located between the oscillation circuit 2 and the frequency control circuit 15.

Reference numeral 23 indicates the TM010 mode resonator disposed at the central portion of the dielectric resonator chip 21. The TM010 mode resonator 23 includes the resonator electrodes 23A and 23B respectively disposed on the front surface and the back surface at the center of the dielectric substrate 22. The resonator electrodes 23A and 23B, which are formed generally in a circular shape and are formed of a conductive thin film, such as a metallic material, are located opposite to each other, and the diameters of the resonator electrodes 23A and 23B are set in accordance with the resonant frequency.

Between the two resonator electrodes 23A and 23B, the resonator electrode 23B disposed on the back surface of the dielectric substrate 22 is connected to the land 19 by using bumps 26, which are discussed below, and are connected to the ground terminal 4 with the through-hole 20 therebetween.

Reference numerals 24 and 25 indicate the excitation electrodes disposed on the back surface of the dielectric substrate 22. The excitation electrodes 24 and 25 are located substantially symmetrically to each other across the resonator electrode 23B, and are formed, together with the resonator electrode 23B, by using the same conductive thin film as that forming the resonator electrode 23B by sputtering or vapor-deposition. The excitation electrodes 24 and 25 respectively include coupling portions 24A and 25A extending in an arch-like shape along the outer periphery of the resonator electrode 23B separately from the resonator electrode 23B, and also include connecting portions 24B and 25B extending from the centers of the coupling portions 24A and 25A toward the edges of the dielectric substrate 22. The overall configuration of the excitation electrodes 24 and 25 are substantially the shape of T.

The connecting portion 24B of the excitation electrode 24 is connected to the microstrip line 5 of the oscillation circuit 2 by using a bump 26, which is discussed below. The connecting portion 25B of the excitation electrode 25 is connected to the microstrip line 16 of the frequency control circuit 15 by using a bump 26.

Reference numeral 26 indicates the bumps for fixing the dielectric substrate 22 to the oscillation circuit substrate 1. The bumps 26 are formed of a conductive metallic material, for example, gold, and are used for fixing the dielectric resonator chip 21 to the oscillation circuit substrate 1. More specifically, the bumps 26 are attached to the land 19 and the connecting portions 5A and 16A of the microstrip lines 5 and 16 in advance, and in this state, the dielectric resonator chip 21 is mounted on the oscillation circuit substrate 1 to perform flip-chip bonding to press the bumps 26. The bumps 26 connect the land 19 to the resonator electrode 23B of the TM010 mode resonator 23 and also connect the connecting portions 5A and 16A of the microstrip lines 5 and 16 to the excitation electrodes 24 and 25, respectively.

The oscillator device of this embodiment is configured as described above, and the operation thereof is as follows.

When a drive voltage is applied to the power terminal 1A, a signal in accordance with the resonant frequency of the dielectric resonator chip 21 (TM010 mode resonator 23) is input into the gate terminal G of the FET 3. In this case, the oscillation circuit 2 and the dielectric resonator chip 21 form a band-reflection-type oscillation circuit. Accordingly, the FET 3 amplifies the signal in accordance with the resonant frequency of the TM010 mode resonator 23 and outputs the amplified signal to the outside via the output terminal 1B.

Additionally, the frequency control circuit 15 including the variable capacitance diode 17 is connected to the dielectric resonator chip 21. Thus, the frequency control circuit 15 can variably set the resonant frequency of the dielectric resonator chip 21 in accordance with the control voltage applied to the control input terminal 1C. With this operation, the overall oscillator device functions as a voltage controlled oscillator (VCO).

Generally, when comparing the unloaded Q (Qo) of a TM010 mode resonator with that of a TE010 mode resonator, the unloaded Q (Qo) of the TE010 mode resonator is higher (better) (Qo in Table 1). As in this embodiment, however, when a multilayered counteractive resonance circuit is formed by using the resonator and the oscillation circuit 2, the unloaded Q is decreased compared to when the resonator is used singly. Accordingly, the unloaded Q of the TE010 mode is not always higher than that of the TM010 mode. Thus, counteractive resonance circuits were formed, as in this embodiment, by using a TM010 mode resonator and a TE010 mode resonator, and the characteristics of the counteractive resonance circuits were compared. The results of the characteristics of the two resonators are shown in Table 1.

TABLE 1

| | TM010 Mode | | TE010 Mode | |
|---|---|---|---|---|
| | Resonator | | Resonator | |
| Resonant Frequency | 38.031 | GHz | 38.203 | GHz |
| Reflection Loss (RL) | 1.9 | dB | 2.6 | dB |
| Load Q (QL) | 102 | | 132 | |
| External Q (Qe) | 127 | | 178 | |
| Unloaded Q (Qo) of Single Resonator | 728 | | 1200 | |
| Decreased Unloaded Q (Qo′) | 524 | | 510 | |

The above results show that a decrease in the unloaded Q is smaller when the TM010 mode resonator 23 is used than when the TE010 mode resonator is used even if strong coupling is established. Accordingly, in the oscillator device of this embodiment, the reflection loss caused by the TM010 mode resonator 23 can be made smaller, thereby obtaining a high oscillation output. Additionally, since strong coupling can be established without seriously decreasing the unloaded Q of the TM010 mode resonator 23, a voltage controlled oscillator that can perform wide-band modulation can be provided.

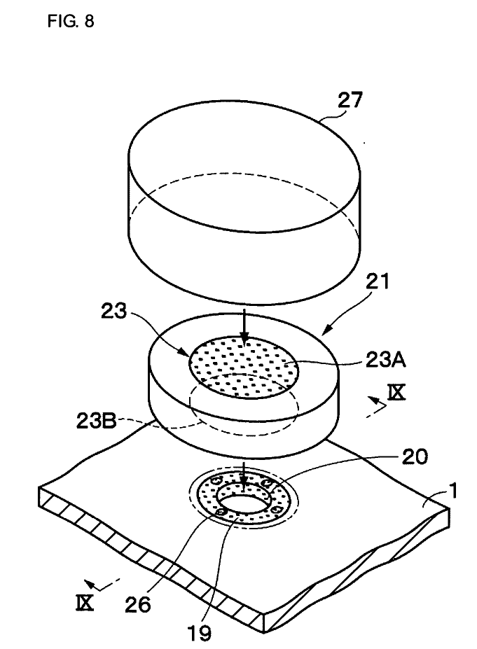

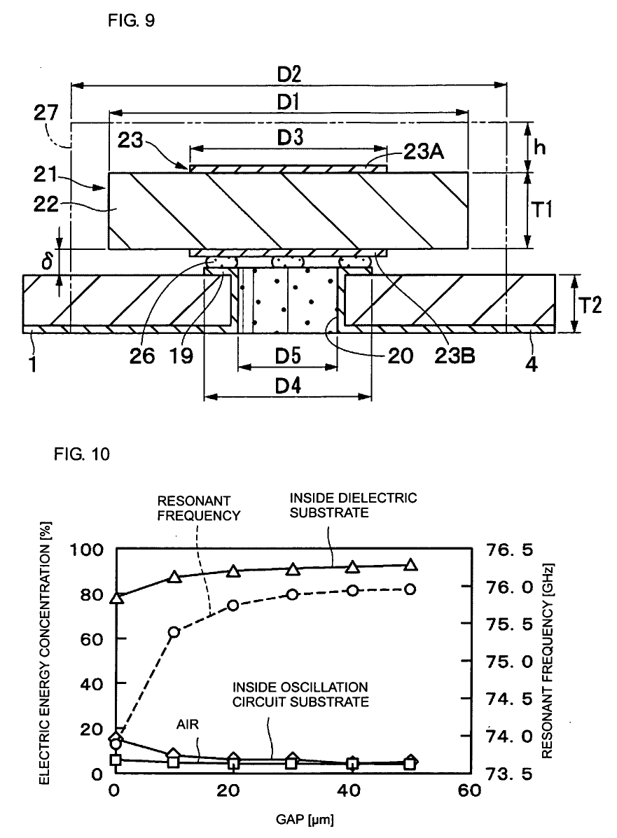

By using the finite element method (FEM) for an axis-symmetrical two-dimensional computation model shown in FIGS. 8 and 9, each electric energy concentration inside the dielectric substrate 22, the oscillation circuit substrate 1, and air space was calculated. The results are shown in FIG. 10.

The results shown in FIG. 10 are obtained under the following conditions: the thickness T1 of the dielectric substrate 22 is 0.3 mm, the external diameter D1 of the circular dielectric substrate 22 is 1.4 mm, the thickness T2 of the oscillation circuit substrate 1 is 0.2 mm, the external diameter D2 of the circular oscillation circuit substrate 1 is 1.7 mm, the external diameter D3 of the resonator electrodes 23A and 23B is 0.8 mm, the external diameter D4 of the land 19 is 0.6 mm, and the internal diameter D5 of the through-hole 20 is 0.4 mm. The thicknesses of the resonator electrodes 23A and 23B and the land 19, etc., do not count (0 μm), and a conductive cover 27 is provided over the front surface of the dielectric resonator chip 21 at a position away from the dielectric resonator chip 21 by a dimension h of 0.3 mm.

The results in FIG. 10 show that the electric energy concentration within the dielectric substrate 22 is very high (90% or higher) when the gap δ between the dielectric substrate 22 and the oscillation circuit substrate 1 is 20 μm or greater, exhibiting a high energy confinement characteristic by the dielectric resonator chip 21. The results in FIG. 10 also show that the fluctuation rate of the resonant frequency is about 0.1% when the gap δ ranges from 30 to 50 μm, exhibiting a very stable resonant frequency characteristic. Accordingly, in this embodiment, even the height (thickness) of the bumps 26 is varied in a range from 30 to 50 μm when mounting (bump-mounting) the dielectric resonator 21 on the oscillation circuit substrate 1 by using the bumps 26, variations in the resonant frequency are very small. It is thus possible to obtain oscillator devices exhibiting high mass productivity.

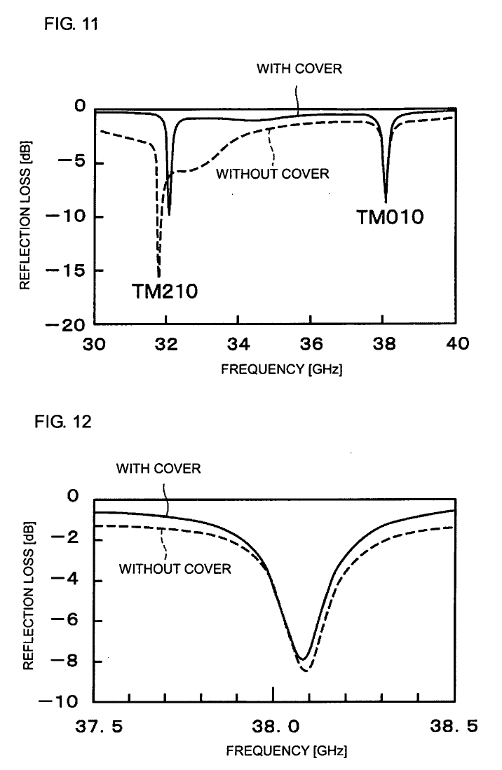

An oscillator device was fabricated by forming the oscillation circuit substrate 1 by using an alumina material and by mounting the 38-GHz dielectric resonator chip 21 on the oscillation circuit substrate 1. Then, the reflection losses (RL) of the dielectric resonator chip 21 of the oscillator device with a conductive cover (not shown) and that without a conductive cover were measured. The results are shown in FIGS. 11 and 12.

The results in FIGS. 11 and 12 are obtained under the following conditions: the thickness of the oscillation circuit substrate 1 is 0.2 mm and the thickness of the dielectric substrate 22 is 0.4 mm. In this case, the dielectric substrate 22 has a square shape having 2.5 mm×2.5 mm dimensions and a relative dielectric constant εr of 24. If the dielectric resonator chip 21 is provided with a cover, the spatial height between the surface of the dielectric substrate 22 and the cover is 0.6 mm, and the cover has a square box-like shape having 3 mm×3 mm dimensions.

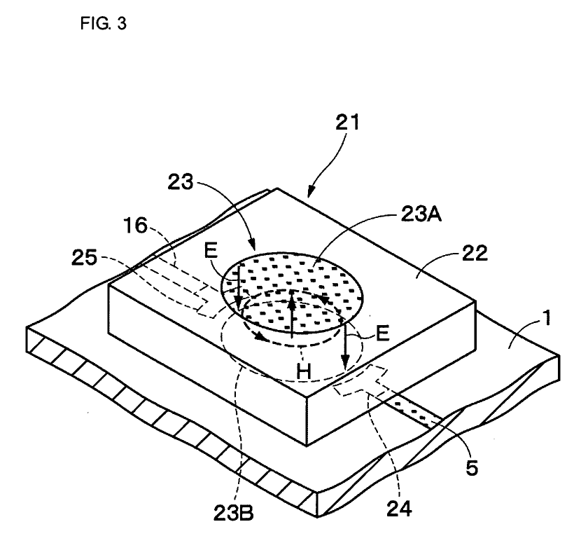

The results in FIGS. 11 and 12 show that the TM010 mode resonance characteristics (resonant frequency and reflection loss) do not change considerably regardless of whether a cover is provided and that the fluctuation rate of the resonant frequency is 0.1% or less. The reason for this is as follows. In the TM010 mode resonator 23 of this embodiment, electric energy (electric fields E and magnetic fields H) concentrates in the dielectric resonator 22 substantially without leaking to the outside (see FIG. 3).

That is, the electric fields E concentrate between the resonator electrodes 23A and 23B while extending in the thickness direction of the dielectric substrate 22, and also, the magnetic fields H are generated concentrically relative to the central positions of the resonator electrodes 23A and 23B and are reflected at the boundary between the end face (opened end) of the dielectric substrate 22 and air substantially without leaking to the outside.

By the use of a TE010 mode resonator, as in the related art, magnetic fields are generated in the thickness direction (height direction) of the dielectric substrate while leaking to the outside of the dielectric substrate.

Accordingly, in the TE010 mode resonator, the characteristics of the TE010 mode resonator are greatly influenced by the presence or absence of a cover because of the magnetic fields, and the fluctuation rate of the resonant frequency is likely to be larger.

In contrast, in this embodiment, by the use of the dielectric resonator chip 21 including the TM010 mode resonator 23, variations in the resonant characteristics depending on the presence or absence of a cover become smaller than those by the use of the TE010 mode resonator. Thus, the provision of a cover on the dielectric resonator chip 21 is not necessary, which simplifies a resonator device package, thereby improving the productivity.

The resonance characteristics of the TM210 mode, which is a higher mode, are considerably varied, as shown in FIG. 11, depending on the presence or absence of a cover.

Accordingly, in this embodiment, effective characteristics can be exhibited when the TM010 mode, which is the fundamental mode, is used.

Thus, in this embodiment, since both the TM010 mode resonator 23 and the excitation electrodes 24 and 25 are disposed on the dielectric substrate 22, variations in the coupling amount between the TM010 mode resonator 23 and the excitation electrodes 24 and 25 can be smaller than those when, for example, the excitation electrodes 24 and 25 are disposed on the oscillation circuit substrate 1. As a result, the characteristics of the individual resonator devices can be maintained substantially at the constant level. Additionally, since the dielectric resonator chip 21 is formed of the TM010 mode resonator 23 and the excitation electrodes 24 and 25, the provision of a frequency control circuit and a terminating resistor on the dielectric substrate 22 can be omitted, thereby reducing the size of the dielectric substrate 22, which is expensive since it has a high dielectric constant. As a result, by a reduction in variations in the characteristics, the mass productivity of the oscillator devices can be increased, and by the use of the small dielectric substrate 22, the manufacturing cost can be decreased.

Further, the resonator electrode 23B disposed on the back surface of the dielectric substrate 22 is connected to the land 19 disposed on the front surface of the oscillation circuit substrate 1, and the land 19 is connected to the ground electrode 4 of the microstrip lines 5 and 16 via the through-hole 20 passing through the oscillation circuit substrate 1. With this configuration, the provision of cavities for the TM010 mode resonator 23 at the side of the oscillation circuit substrate 1 (back surface of the dielectric substrate 22) becomes unnecessary. As a result, the structure of the oscillator device can be simplified to reduce the manufacturing cost, and also, the height of the overall device can be decreased.

Also at the side of the TM010 mode resonator 23 (front surface of the dielectric substrate 22) opposite to the oscillation circuit substrate 1, the radiation of magnetic fields is smaller than that when a TE010 mode resonator is used, and the frequency sensitivity is small in response to the height of cavities. Thus, it is not necessary to form cavities using a conductive cover. As a result, the height of the overall resonator device can be decreased, and the structure of the resonator device (package structure) can be simplified, thereby improving the mass productivity and decreasing the manufacturing cost.

The resonator electrode 23B of the TM010 mode resonator 23 is connected to the land 19 by using the bumps 26, such as gold. Accordingly, the dielectric resonator chip 21 is less likely to be displaced after connection compared to when the resonator electrode 23B is connected to the land 19 by using a conductive paste, thereby achieving a connection with high positional precision. Additionally, as in the related art, when ribbons or wires are used for connecting the resonator electrode 23B with the land 19, the resonance characteristics of the TM010 mode resonator 23 are likely to vary due to inductor components of the ribbons, etc. In this embodiment, however, since the bumps 26 are used for connecting the resonator electrode 23B with the land 19, the characteristics, such as the resonant frequency, can be maintained substantially at the constant level even if the height of the bumps 26 varies in a range from 30 to 50 μm. Accordingly, variations in the characteristics due to the mounting operation of the dielectric resonator chip 21 can be reduced. As a result, the mass productivity of the resonator devices can be improved.

Moreover, the frequency control circuit 15 for controlling the oscillating frequency (resonant frequency) is provided on the oscillation circuit substrate 1, and is connected to the TM010 mode resonator 23 through the excitation electrode 25, which is different from the excitation electrode 24, disposed on the dielectric substrate 22. With this configuration, as in this embodiment, when a counteractive resonance circuit is formed by using the TM010 mode resonator 23, a decrease in the unloaded Q (Qo) can be suppressed compared to that when a TE010 mode resonator is used. Accordingly, the reflection loss caused by the TM010 mode resonator 23 becomes small, and a high oscillation output can be expected. Additionally, strong coupling between the TM010 mode resonator 23 and the frequency control circuit 15 can be established without seriously decreasing the unloaded Q of the TM010 mode resonator 23. It is thus possible to form a voltage controlled oscillator that can perform wide-band modulation by using the frequency control circuit 15.

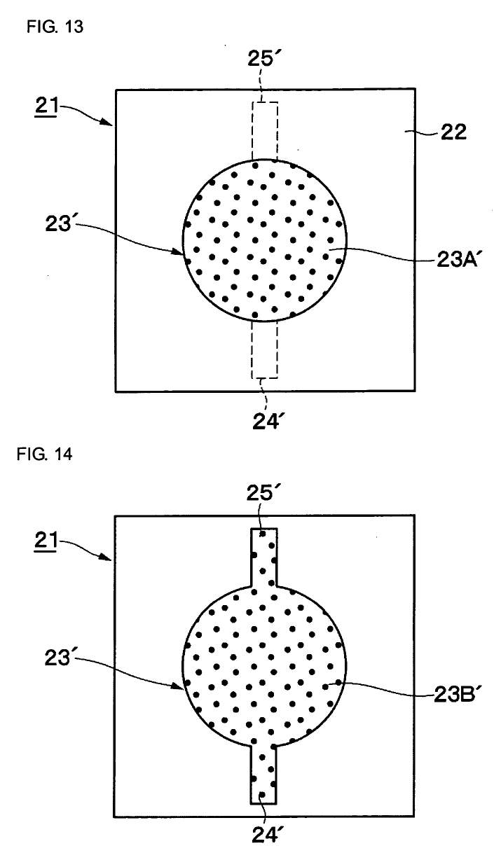

In the above-described first embodiment, the resonator electrodes 23A and 23B of the TM010 mode resonator 23 are disposed separately from the excitation electrodes 24 and 25, respectively, and they are coupled with each other through gaps. However, the present invention is not restricted to this configuration, and, for example, as in a first modified example shown in FIGS. 13 and 14, a resonator electrode 23B′ may be directly connected to excitation electrodes 24′ and 25′ without gaps. In this case, to prevent the generation of electromagnetic fields in the oscillation circuit substrate, a circular hole is formed in the portion of the oscillation circuit substrate opposing the resonator electrode 23B′. The resonator electrode 23A′ is connected to a ground by using a ribbon, a wire, or a through-hole.

In the first embodiment, the microstrip lines 5 and 16 are used as the transmission lines provided on the oscillation circuit substrate 1. However, the present invention is not restricted to this configuration, and grounded coplanar lines having ground electrodes may be provided on the back surface of the oscillation circuit substrate 1.

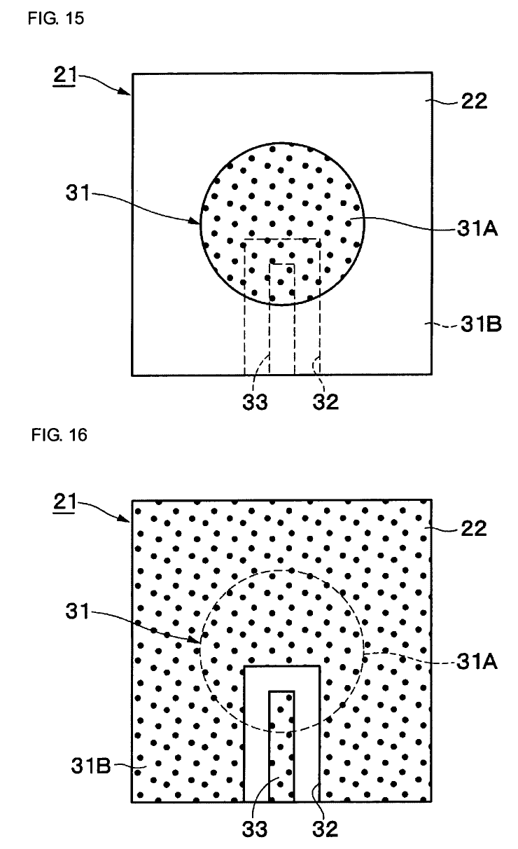

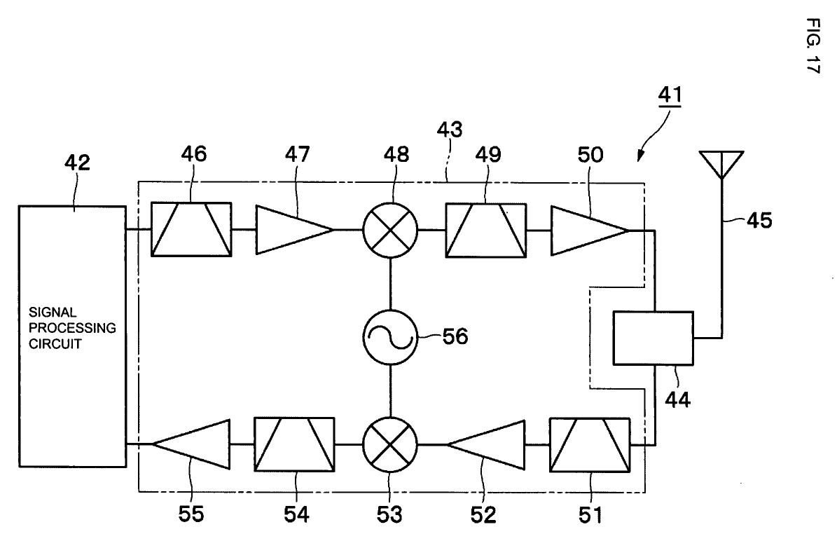

Moreover, in the first embodiment, both the resonator electrodes 23A and 23B of the TM010 mode resonator 23 are formed in a circular shape. However, it is sufficient if one of the resonator electrodes 23A and 23B is formed in a circular shape. Accordingly, as in a second modified example shown in FIGS. 15 and 16, a TM010 mode resonator 31 may be configured as follows. A circular resonator electrode 31A is disposed on the front surface of the dielectric substrate 22, while a resonator electrode 31B is disposed on the back surface of the dielectric substrate 22 such that it covers the entire back surface.

In this case, when connecting the TM010 mode resonator 31 to, for example, coplanar lines or ground coplanar lines, a band-like notch 32 is provided for the resonator electrode 31B, and an excitation electrode 33 to be connected to the signal lines, such as coplanar lines, is formed in the notch 32, and the resonator electrode 31B is connected to a ground. With this configuration, the resonator electrode 31B disposed on the back surface of the dielectric substrate 22 can be connected to the ground electrodes, such as coplanar lines, disposed on the front surface of the oscillation circuit substrate. This eliminates the need to provide cavities on the back surface of the dielectric substrate 22 of the TM010 mode resonator 31. Also on the front surface of the dielectric substrate 22, since the resonant frequency sensitivity is small in response to the presence or absence of a cover, it is not necessary to form cavities using a conductive cover. As a result, the height of the overall resonator device can be made smaller, and the structure of the resonator device can be simplified, thereby improving the mass productivity and decreasing the manufacturing cost.

FIG. 17 illustrates a second embodiment of the present invention. This embodiment is characterized in that a communication device is formed as a transmission and reception device by using the oscillator device.

Reference numeral 41 indicates a communication device of this embodiment. The communication device 41 includes a signal processing circuit 42, a high-frequency module 43 connected to the signal processing circuit 42 to input or output high-frequency signals, and an antenna 45 connected to the high-frequency module 43 to transmit or receive high-frequency signals via an antenna duplexer 44.

In the high-frequency module 43, a transmission side is formed by a band-pass filter 46, an amplifier 47, a mixer 48, a band-pass filter 49, and a power amplifier 50 connected between the output side of the signal processing circuit 42 and the antenna duplexer 44. The reception side is formed by a band-pass filter 51, a low-noise amplifier 52, a mixer 53, a band-pass filter 54, and an amplifier 55 connected between the antenna duplexer 44 and the input side of the signal processing circuit 42. An oscillator device 56, such as that configured as in the first embodiment, is connected to the mixers 48 and 53.

The communication device of this embodiment is configured as described above, and the operation thereof is as follows.

When transmitting a signal, after removing unwanted signal components in the band-pass filter 46, an intermediate frequency signal (IF signal) output from the signal processing circuit 42 is amplified by the amplifier 47 and is input into the mixer 48. Then, the mixer 48 mixes the IF signal with a carrier wave supplied from the oscillator device 56 to up-convert the IF signal to a high-frequency signal (RF signal). After removing unwanted signal components in the band-pass filter 49, the high-frequency signal output from the mixer 48 is amplified to transmission power by the power amplifier 50 and is transmitted from the antenna 45 via the antenna duplexer 44.

When receiving a signal, a high-frequency signal received from the antenna 45 is input into the band-pass filter 51 via the antenna duplexer 44. After removing unwanted signal components of the high-frequency signal in the band-pass filter 51, the high-frequency signal is amplified by the low-noise amplifier 52 and is input into the mixer 53. Then, the mixer 53 mixes the high-frequency signal with a carrier wave supplied from the oscillator device 56 to down-convert the high-frequency signal to an IF signal. Then, after removing unwanted signal components in the band-pass filter 54, the IF signal output from the mixer 53 is amplified by the amplifier 55 and is input into the signal processing circuit 42.

As is seen from the foregoing description, according to this embodiment, a communication device using the oscillator device 56 that can perform high output and wide-band modulation can be formed. Thus, the resulting communication device can be used over a wider band. Additionally, since the small and mass-productive oscillator device 56 is used, the communication device can be miniaturized, and the manufacturing cost can be decreased.

In the second embodiment, the oscillator device 56 of the present invention is applied to the communication device 41 by way of example. However, the oscillator device 56 may be applied to, for example, a radar device.

1. An oscillator device comprising:
an oscillation circuit substrate;
an oscillation circuit disposed on the oscillation circuit substrate to oscillate a signal having a predetermined oscillating frequency; and
a dielectric resonator for setting the oscillating frequency, the dielectric resonator including:
a dielectric substrate mounted on a front surface of the oscillation circuit substrate;
a TM010 mode resonator having a first electrode disposed on a first surface of the dielectric substrate and a second electrode disposed on a second surface of the dielectric substrate, at least one of the first and second electrodes being circular; and
an excitation electrode disposed on the dielectric substrate, the excitation electrode being connected to the oscillation circuit and being coupled with the TM010 mode resonator.

2. The oscillator device according to claim 1, wherein the oscillation circuit includes a transmission line disposed on the surface of the oscillation circuit substrate and a ground electrode, and
at least one of the first and second electrodes of the TM010 mode resonator, is connected to a land disposed on the surface of the oscillation circuit substrate, and the land is connected to the ground electrode.

3. The oscillator device according to claim 2, wherein the at least one of the first and second, electrodes of the TM010 mode resonator, is connected to the land with bumps.

4. The oscillator device according to claim 1, wherein the oscillation circuit includes a transmission line and a ground electrode on the surface of the oscillation circuit substrate, and
at least one of the first and second electrodes of the TM010 mode resonator, is connected to the ground electrode disposed on the surface of the oscillation circuit substrate.

5. The oscillator device according to claim 1, further comprising:
a frequency control circuit for controlling the oscillating frequency, the frequency control circuit being disposed on the oscillation circuit substrate; and
a second excitation electrode disposed on the dielectric substrate, the second excitation electrode coupled with the TM010 mode resonator and connected to the frequency control circuit.

6. A transmission and reception device using the oscillator device set forth in claim 1.

7. The oscillator device according to claim 2, wherein the surface of the oscillation circuit substrate is a first surface, and the ground electrode is disposed on a second surface of the oscillation circuit substrate, the second surface opposing the first surface.

8. The oscillator device according to claim 7, wherein the land is connected to the ground electrode via a through-hole passing through the oscillation circuit substrate.
